(19) United States
(12) Patent Application Publication
(10) Pub. No.: US 2026/0354071 A1
(43) Pub. Date: Nov. 5, 2026

(54) A METHOD FOR SEPARATING A COMPREHENSIVE SUBSTRATE INTO A FIRST SUBSTRATE AND A SECOND SUBSTRATE AND A DEVICE FOR SUCH A METHOD

(71) Applicant: EV Group E. Thallner GmbH, ST. FLORIAN AM INN (AT)

(72) Inventor: Thomas PLACH, St. Florian am Inn (AT)

(21) Appl. No.: 19/486,991

(22) PCT Filed: May 25, 2023
(86) PCT No.: PCT/EP2023/063989

§ 371 Date: Nov. 24, 2025

(51) Int. Cl. H10P 56/00; H10P 70/00; H10P 72/00; H10P 72/76

(52) U.S. Cl. CPC H10P 56/00; H10P 70/27; H10P 72/0428; H10P 72/7621

(57) ABSTRACT

A method for separating a comprehensive substrate (3) into a first substrate (13) and a second substrate (23), wherein the first substrate (13) and/or the second substrate (23) is intended to be an element of an electronic component, comprising
providing the comprehensive substrate (3) comprising the first substrate (13) and the second substrate (23), wherein the first substrate (13) and the second substrate (23) are bonded with each other along a bonding interface via a created bond, preferably via a bond created by a fusion bond, and
separating the comprehensive substrate (3) into the first substrate (13) and the second substrate (23) along the bonding interface,
   wherein an agent for chemical processing and preferably a non-chemical mean are used for separating the comprehensive substrate (3) into the first substrate (13) and the second substrate (23).

The present invention relates to a method for separating a comprehensive substrate into a first substrate and a second substrate, and to a device for such a method.

As miniaturization progresses, there is an increasing need for more powerful, smaller, thinner and faster electronic devices, which require correspondingly smaller, thinner, more powerful and faster chips.

According to Moore's observation, the computing capacity of chips is increased in order to increase their performance. This is accompanied by smaller chips with a large number of vias and contacts and, in particular, chips are produced stacked from layers of the same or different circuits.

For stacking the layers, thin-film technology can be used at the transistor level or finished, thinned chips or substrates can be aligned with each other and bonded together, in particular bonded.

The Hybrid bond and fusion bond technology, which can preferably be used to manufacture SOI substrates, memory units, MEMS components or image sensors, requires continuously improved quality control of the substrates joined together. Fusion bonds and/or hybrid bonds are used in the prebond to hold the substrates together primarily by means of Van der Waals forces. A Subsequent heat treatment permanently bonds the comprehensive substrate together. In the case of a hybrid bond, the metallic vias and contacts are bonded with each other during heat treatment.

During the quality control of the prebond, alignment errors, particles or gas inclusions in particular can be found, which would lead to intolerable defects that require correction.

With permanent bonding processes, it is not possible to correct the bonded comprehensive substrate, which means that the defective substrates or chips can only be sorted out. In particular, comprehensive substrates bonded in the prebond using a fusion bond can be separated from each other non-destructively, so that the substrates can be rejoined after separating. In the prior art, fusion-bonded comprehensive substrates have been separated by so-called debonding processes for several years, as disclosed, for example, in U.S. Pat. No. 9,806,054 B2.

Separating the comprehensive substrate joined with fusion bonds in the prebond and re-joining it proves to be a technologically and financially sensible option compared to sorting out comprehensive substrates, especially if the substrates are assigned to a different pairing in order to compensate for the incorrect alignment or distortions measured on the comprehensive substrate that exceed the tolerance values.

The substrates separated by said means are cleaned and optionally surface activated again, then realigned again with each other and fusion bonded together.

The bond strength of fusion-bonded comprehensive substrates has been continuously increased in recent years, as the substrates are held together in the prebond with the optimized surface activation by means of plasma treatment with increased bonding force.

In particular, plasma activation ensures that a reservoir is created in at least one of the two substrates in which a fluid, in particular water, can be stored. After bonding of the two substrates, this stored water results in several physical and chemical changes that can lead to an improvement in the bond strength even at relatively low temperatures. These effects are explained in detail in the publications WO2012100786A1, WO2012136267A1, WO2012136268A1, WO2012136266A1 and WO2014015899A1.

Subsequent heat treatment to achieve the final strength of the bonding can thus be processed at lower temperatures and/or with a shorter time. The increased strength of the prebond reduces the chance to open the defectively bonded comprehensive substrate without destroying it.

The approaches of mechanical detachment of a first substrate from the second substrate, as disclosed in U.S. Pat. No. 9,296,193 B2 or in U.S. Pat. No. 9,922,862 B2, which are also used in temporary bonding and debonding, cannot be adapted without risking substrate breakage.

It is therefore the task of the present invention to disclose a modified debonding process for fusion-bonded substrates in which stronger prebonds can be separated.

The present invention solves the problem with a method according to claim 1 and a device according to claim 13. Further advantageous embodiments can be found in the description, the dependent claims and the figures. All combinations of at least two of the features specified in the description, the claims and/or the drawings also fall within the scope of the invention. In the case of value ranges, values lying within the stated limits are also to be disclosed as limit values and can be claimed in any combination.

According to a first aspect, a method for separating a comprehensive substrate into a first substrate and a second substrate is provided, wherein the first substrate and/or the second substrate is intended to be an component of an electronic or electromechanical device, comprising the following steps:
providing the comprehensive substrate comprising the first substrate and the second substrate, wherein the first substrate and the second substrate are bonded with each other along a bonding interface via a bond created, preferably via a bond created by a fusion bond,
wherein the comprehensive substrate is a non-destructively releasable bond, in particular a prebond, and
separating the comprehensive substrate into the first substrate and the second substrate along the bonding interface,
wherein an agent for chemical processing and preferably a means for non-chemical processing is used for separating the comprehensive substrate into the first substrate and the second substrate.

In contrast to the methods known from the prior art, it is intended according to the invention that an agent for chemical processing is used and, in particular, is combined with a means for non-chemical processing when separating along the bonding interface. The agent for chemical processing and the means for non-chemical processing preferably act together simultaneously or successively on the bonding interface of the comprehensive substrate. The first substrate and the second substrate are bonded with each other via the bonding interface in the comprehensive substrate. It has been shown that this allows separating to take place in a more controlled manner, i.e. largely without uncontrolled breakage. In particular, it has been found that a mechanical separating force, which emanates in particular from the means for non-chemical processing, can be reinforced with the effect of a chemical solvent during the separation of a fusion-bonded comprehensive substrate, thereby allowing the bonds of a prebond to be broken. This reduces the mechanical separating force required for separating and reduces the risk of substrate breakage. This ensures that the first substrate and/or the second substrate can be used again after separating. For example, the first substrate and the second substrate can be joined together again. Separating can also be accelerated. The means for non-chemical processing can also be an optical means, in which, for example, laser light is used, a means for irradiation, for example with light or particles, in particular ions, and/or a mechanical means, in which, for example, a cutting edge acts on a region of the bonding interface for separating along a separation plane or along the bonding interface. The means for non-chemical processing can be a system, in particular a substrate holding system, which, for example, causes the first substrate and the second substrate to be pulled apart. The means for non-chemical processing preferably causes a separating force that acts mechanically on the first substrate and the second substrate. This emanates, for example, from substrate holders that are attached to the first substrate and the second substrate if, in the comprehensive substrate, the first substrate and the second substrate are still bonded with each other via the bonding interface. In this case, the non-chemical, in particular mechanical, means is formed by the first substrate holder and/or the second substrate holder, from which a mechanical separating force is exerted during separating.

Preferably, the comprehensive substrate is a non-destructively separable fusion bond without heat treatment. The prebond describes a state of the fusion bond in which the two substrates are only bonded together by Van der Waals forces. This bonding process takes place primarily between silicon substrates and/or silicon oxide substrates or other non-metallic, preferably dielectric substrates, preferably semiconductor substrates. The bond produced in this way is referred to as a prebond, as it is a preliminary stage to a permanent bond. In the semiconductor industry, it is very often desirable to release a (temporary) bond created by a prebond if it is found after joining that the two substrates have not been optimally or even incorrectly aligned with each other. Preferably, the separating proceeds along a separation plane which extends along a bonding interface or the bonding interface which extends between the first and second substrates and is most preferably created or formed by the fusion bonding. The bonding interface thus differs from the first substrate and/or second substrate in terms of its physical and/or chemical properties. This separation plane or bonding interface most preferably runs along a plane parallel to the main extension plane of the substrates, the main extension plane being predetermined by a general course of the comprehensive substrate, the first substrate and the second substrate. The chemical bonds that exist between the two bonded substrates are at least partially broken with a solvent. The solvent acts on the existing bonds between the substrate surfaces of the comprehensive substrate to be separated, thereby reducing the separating force required for complete de-bonding, in particular the mechanical separating force. In particular, the solvent has a locally corrosive effect on the bonds of the prebond, so that a type of stress corrosion facilitates separation along the separation plane. According to the invention, it is conceivable to use a fluid, i.e. gases and/or liquids, as an agent for chemical processing.

An electrical component is to be understood, for example, to be a chip or an element of a circuit board. In particular, the electrical component comprises electrical vias and/or electrical connections. The electrical component further preferably comprises a conductor track structure.

For example, it is intended that the first substrate and the second substrate are bonded with each other again after separating, preferably via a fusion bond. This makes it advantageously possible to incorporate the separating method in a correction mechanism in which an unwanted offset between the first substrate and the second substrate has been detected and separating has subsequently become necessary for correction. Furthermore, it is advantageously possible to incorporate the separating method in a correction mechanism in which particles were detected between the first substrate and the second substrate and separating was subsequently required for cleaning and correction.

According to a preferred embodiment, it is intended that a mechanical tool is used as the means for non-chemical processing or as a further means for non-chemical processing.

Most preferably, it is intended that the mechanical tool interacts with the comprehensive substrate, in particular at the bonding interface. A cutting means, such as a blade, is conceivable as a mechanical tool. In particular, the mechanical tool acts on the comprehensive substrate in addition to exerting a force, the force being exerted by holders to which the first substrate and the second substrate are bonded and acting on the comprehensive substrate. Most preferably, the mechanical tool acts on the comprehensive substrate along a direction that is essentially parallel to the main extension plane. In one conceivable embodiment, the mechanical tool may comprise at least two separating elements, in particular separating blades or separating wires, which act mechanically on the comprehensive substrate from two opposite sides, in particular simultaneously, in order to separate the first substrate and the second substrate from one another. In particular, it is preferably intended that the tool acts on the bonding interface in addition to a separating force that emanates from the substrate holding system and attempts to pull the first substrate and the second substrate apart.

In a further preferred embodiment, it is intended that a solvent is used as the agent for chemical processing. In particular, it is intended that a fusion-bonded comprehensive substrate is in a chemical reaction equilibrium. If the reaction equilibrium is shifted according to Le Chatelier's principle by exposing the fusion-bonded comprehensive substrate to a solvent which resolves the bond of the prebond in the bonding interface, the equilibrium is shifted in such a way that the substrates are separated from one another as a result of the action of the solvent. The person skilled in the art specifically uses solvents for the comprehensive substrate that shift the reaction equilibrium in the bonding interface, preferably according to Le Chatelier's principle, and thus separate the comprehensive substrate. To accelerate the chemical separation reaction, the non-chemical agent, preferably a complementary mechanical tool, is preferably used.

One possible important chemical reaction of a substrate surface terminated with hydroxyl groups is

Si—OH(s)+Si—OH(s)←→Si—O—Si(s)+H₂O (1)

This chemical equilibrium reaction describes the conversion of hydroxyl groups under a condensation reaction to a silicon oxygen compound with the separation of water. The Si atoms each come from one of the two substrates that form the comprehensive substrate.

The oxygen bonds them together.

Preferably, it is intended that the solvent is incorporated in the first substrate and/or second substrate, in particular in such a way that oversaturation is set in the region of the bonding interface. The first substrate and/or the second substrate is thus designed, in particular due to its porous configuration, to serve as a reservoir with which a reaction direction of an equilibrium reaction is influenced.

The accumulation takes place after the prebond, but in any case during the heat treatment. The aforementioned activation of at least one of the two substrate surfaces allows the accumulation of a fluid, in particular water. However, this water, which is stored in the reservoir before bonding, is required for other physical and chemical effects, which will not be discussed in detail here. It is important to understand that once the water has been used up, the reservoir is empty for the most part and can be refilled. If, after a fusion bond has been carried out in the prebond, it is determined that the two substrates need to be separated again, the comprehensive substrate can be placed in a solvent, in particular water. This water then diffuses not only across the interface but also across the reservoir to the upper and/or lower side of the interface, i.e. the bonding interface, and exerts a constraint on the above-mentioned chemical equilibrium, in accordance with Le Chatelier's principle. Since there is an excess of water, the above-mentioned chemical equilibrium reacts in such a way that it avoids the external constraint, i.e. the excess of water. The chemical equilibrium thus reacts to the left and splits the Si-O-Si bond under hydrolysis. It is thus preferably intended that a chemical bond in the region of the bonding interface is separated under hydrolysis.

An important aspect is therefore the oversaturation of the interface with a solvent, in particular water, via an existing porous reservoir.

In particular, it is intended that the comprehensive substrate is placed in a solvent bath. It is preferably provided that the comprehensive substrate and the solvent bath are designed in such a way that the bonding interface is arranged below a solvent surface or below a level of the solvent so that the solvent can permanently act on the bonding interface until complete separating between the first substrate and the second substrate is intended. A solvent bath is a particularly energy-saving method of promoting chemically induced separating.

For the solvent bath, a trough is intended in particular to provide the solvent. Preferably, it is conceivable that the solvent bath comprises means by which penetration of the solvent into a notch between the first substrate and the second substrate or substitution of the solvent in the notch between the first substrate and the second substrate is promoted. As a result, unused solvent is preferably provided at the bonding interface to be separated. For example, a means is conceivable that causes movement of the solvent in the solvent bath.

Most preferably, it is intended that the solvent is directed onto the bonding interface by means of a nozzle element. In particular, a jet of solvent is directed onto the bonding interface. This allows the solvent to effectively support chemical separating when it hits the bonding interface. It is conceivable, for example, that a particularly advantageous release can be set via a jet pressure. A jet of solvent is preferably directed onto a peripherically arranged edge of the comprehensive substrate. It is also conceivable that the bonding interface is acted upon by a plurality of nozzle elements, preferably simultaneously.

It is also conceivable that the tank in which the solvent is located is constructed to be pressure-stable and that the increase in solvent pressure results in an increased diffusion rate of the solvent into the reservoir. This is particularly necessary if the solvent has difficulty penetrating a reservoir with a relatively small pore size due to its surface tension. It is also conceivable to add surfactants in order to reduce the surface tension and facilitate access of the solvent into the reservoir.

It is most preferably intended that a first contribution to the separating reaction is made by the agent for chemical processing and a second contribution is made by the means for non-chemical processing, with a ratio between the first contribution and the second contribution having a value of between 1:99 and 99:1. The ratios of the contributions of the chemical separation reaction to the proportions of the mechanical separation reaction vary from a ratio of chemical contribution to mechanical or optical contribution of 1:99 to 99:1. A ratio of 0:100 would be a purely mechanical/optical separation process without the use of a chemical solvent and a 100:0 would be a purely chemical separation process. For example, to compare and determine the respective proportions, the respective methods are performed individually and a duration for separating is then determined. The respective contribution can be estimated based on these durations.

Furthermore, it is preferably intended that the solvent is replaced, in particular renewed, after a defined number, preferably after each separated comprehensive substrate. This advantageously ensures that the purest possible solvent composition is provided for the next comprehensive substrate, which effectively arranges separating. For example, the solvent is drained from the tank for this purpose.

Furthermore, it is preferably intended that the solvent is an aprotical non-polar solvent and/or an aprotical polar solvent and/or a protical solvent. Preferably, the solvent and/or the solvent mixture (a mixture of at least two solvents) is used specifically for the chemical separation reaction of the comprehensive substrate. The solvent or the solvent mixture may contain one or more components from the lists below:
include aprotical non-polar solvents, in particular alkanes, alkenes, alkynes, aromatics with aliphatic and/or aromatic substituents, esters, in particular of carboxylic acid, ethers, symmetrically structured molecules, carbon-containing solvents with their sulfides and/or oxides, halogenated hydrocarbons, in particular perfluorinated hydrocarbons, and/or
aprotic polar solvents, in particular ketones, lactones, lactams, nitriles, nitro compounds, tertiary carboxylic acid amides, urea derivatives, sulphoxides, sulphones, carbonic acid esters and/or
protic solvents, in particular water, short-chain alcohols, primary and secondary amines, carboxylic acids, primary and secondary amides, mineral acids, and/or 1,1,1-trichloroethane, 1,2-dichloroethane (ethylene dichloride), 1,4-dioxane, 1-butanol, 1-butanol, 1-decanol, 1-octanol, 1-pentanol (amyl alcohol), 1-propanol, 2-butanol, 2-ethyl-1-butanol, 2-ethylhexanol, 2-methyl-1-propanol, 2-methyl-2-propanol (tert-butanol), 2-octanol, 2-propanol, 2-propanol (isopropyl alcohol), 3-methyl-1-butanol (isoamyl alcohol), 4-methyl-2-pentanol (MIBC), acetone, acetonitrile, aniline, anisole, benzene, benzonitrile, benzyl alcohol, bromobenzene, quinoline, chlorobenzene, chloroform, cyclohexane, cyclo-hexanol, DCM), diacetone alcohol, dibutyl ether, diethylene glycol, diethyl ether, dimethyl acetamide, dimethyl formamide, dimethyl sulphoxide, pure acetic acid, acetic anhydride, acetic acid ethyl ester, ethanol, ethanol, ethylene glycol, ethylene glycol dimethyl ether, formamide, hexanol, methanol, methylene chloride (dichloromethane), methyl ethyl ketone (butanone), n-heptane, n-hexane, nitrobenzene, nitromethane, N-methyl-2-pyrrolidone (NMP), N-methyl formamide, n-pentane, petroleum ether/light benzene, piperidine, propanol, propylene carbonate (4-methyl-1,3-dioxol-2-one), pyridine, carbon disulphide, sulfolane, tert-amyl alcohol, tert-butanol, tert-butyl methyl ether (MTBE), tetrachlorethene, carbon tetrachloride, tetrahydrofuran, tetrahydrofurfuryl alcohol, toluene, trichloroethene, triethylamine, triethylene glycol, triethylene glycol dimethyl ether (triglyme), water, γ-butyrolactone. It is most preferably intended that a solvent mixture is used in order to arrange for the best possible adapted resolution of the bonding interface.

The specific solvent used is dependent on the material system to be separated. For the dis-solution of silicon-oxide-silicon-oxide bonds or silicon-silicon-oxide bonds, high-purity distilled water has proven to be advantageous, as this allows the bonds between the substrate surfaces (Si—O—Si bonds) to be separated and the substrate surfaces are then terminated again with OH groups. At this stage, the interaction between the substrates again proceeds via Van der Waals forces, which are known to be much weaker than the forces of the prebond. This means that the substrates of the overall substrate can be chemically and mechanically separated from each other better than with mechanical separation.

Furthermore, it is preferably intended that after separating, the first substrate and/or the second substrate is cleaned by means of a cleaning device and/or dried by means of a drying device. This makes it advantageously possible to remove impurities from the separated first and second substrates, which remain as particles or residues after separation. Most preferably, cleaning is carried out with distilled water or DI-water and drying is carried out in such a way that particle-free surfaces of the separated first substrate and second substrate can be provided. The first substrate and the second substrate can then be joined together, for example.

In particular, it is intended that a solvent supply is adjusted by means of a dosing device.

This makes it advantageously possible to adjust the solvent supply, in particular its dosage and/or concentration, in a targeted manner, preferably as a function of the type and/or properties of the bonding interface. It is conceivable that a dosage and/or a concentration of solvent changes during the treatment for separation. As a result, the separating measures can preferably be further optimized and, in particular, further adapted to the respective requirements.

Most preferably, it is intended that a separating force is arranged to be applied to the first substrate and to the second substrate, wherein the separating force acts substantially perpendicular to a main extension plane of the first and/or second substrate. In other words, the separating force attempts to separate the first substrate and the second substrate from one another, in particular to pull them apart. In particular, this avoids shear forces that would otherwise or possibly act on the first substrate and the second substrate starting from holding fixtures for fixing the comprehensive substrate to the first substrate and the second substrate as long as the first substrate and the second substrate are still bonded with each other via the bonding interface. In this way, the abrasive effect of particles in the bonding interface on the substrate surfaces of the first substrate and the second substrate is preferably avoided.

For example, it is intended that the first substrate is fixed in a first substrate holder and the second substrate is fixed in a second substrate holder, wherein during separating, in addition to the action by the agent for chemical processing, the tool also moves the first substrate holder and the second substrate holder apart.

A first exemplary embodiment of a method according to the invention comprises the following steps, in particular carried out successively and/or simultaneously, in particular with the following sequence:

In preparation for the method for separating bonded comprehensive substrate, the comprehensive substrate is loaded into the device for separating bonded comprehensive substrate. In a first method step, the comprehensive substrate is held in place on a substrate holder, in particular a first substrate holder. In various embodiments of the method, the holding can be carried out with vacuum fixation and/or preferably with mechanical fixation. In a second method step, the comprehensive substrate fixed on a substrate holder is fixed to a second substrate holder, in particular an upper substrate holder. The fixing can be done with vacuum fixation and/or preferably mechanical fixation.

In a third method step, the separation of the comprehensive substrate is initiated by inserting a separating element, preferably a mechanical tool, in particular a blade, between the first substrate and the second substrate of the comprehensive substrate along the original bonding interface. Alternatively, clamping rings on the respective substrate edge of the first substrate and the second substrate can exert a force vertically to the bonding interface in the comprehensive substrate.

In a fourth method step, a solvent for breaking the chemical bonds is introduced into the bonding interface by filling a trough of the device with the solvent to above the level of the bonding interface. Thus, the solvent gradually penetrates into the prising bonding interface and/or an existing reservoir, and separates the first substrate and the second substrate from each other. As an alternative to the fourth method step, the comprehensive substrate can be immersed in a tank already filled with solvent. This merely represents a kinematic reversal for the method.

In a fifth method step, after this initial opening of the bonding interface of the comprehensive substrate and application of solvent to the bonding interface, the substrates are additionally mechanically tensioned. Preferably, they are braced in particular on the side on which the mechanical tool penetrates the bonding interface by applying a vertical tensile force that pulls the first substrate and the second substrate apart in a wedge shape. As a result, solvent continues to flow into the bonding interface, where the mechanical and chemical separation of the comprehensive substrate takes place.

In a sixth method step, as the separation process progresses further, in addition to pulling the substrates apart in a wedge shape, they are also pulled apart vertically by the first and second substrate holders with the respective substrates attached to them gradually moving away from each other, in particular step by step. In a seventh method step, the substrates are completely separated from each other. In an eighth method step, the substrates are cleaned, dried and conveyed by means of a transport device into the storage device, in particular substrate boxes, and deposited.

A second exemplary embodiment of a method according to the present invention comprises the following steps, in particular carried out successively and/or simultaneously, in particular with the following sequence:

In preparation for the method for separating bonded comprehensive substrate, the comprehensive substrate is loaded into the device for separating bonded comprehensive substrate.

In a first method step, the comprehensive substrate is placed on a first substrate holder, in particular a lower substrate holder, and fixed in place. In various embodiments of the method, the holding or fixing can be carried out with vacuum fixing and/or preferably with mechanical fixing. In a second method step, the comprehensive substrate fixed on a substrate holder is fixed to a second substrate holder, in particular an upper substrate holder. The fixing can be carried out with vacuum fixing and/or preferably mechanical fixing.

In a third method step, the separation of the comprehensive substrate is initiated by introducing solvent into the bonding layer of the comprehensive substrate from at least one nozzle element, in particular with comparatively high pressure, in particular with 0.1 bar overpressure, preferably with 0.5 bar overpressure, more preferably with 1 bar overpressure, most preferably with 2 bar overpressure, in the optimum case with 5 bar overpressure. In this way, the solvent gradually penetrates into the breaking bonding interface and separates the substrates from each other. The positioning of the solvent jet in the separation plane and the timing and dosing duration play at least as important a role in the successful separation of the substrate stack as the pressure of the solvent jet.

The outflowing solvent is collected in a drip tray of the separating device. The use of the drip tray can completely be omitted if only a few milliliters of solvent are used. In a fourth method step, after this initial opening of the bonding interface of the comprehensive substrate and application of solvent to the bonding interface, the first substrate and the second substrate are additionally mechanically tensioned. Preferably, they are braced in particular on the side on which the solvent penetrates into the bonding interface from the nozzle element by applying a vertical tensile force that pulls the first and second substrates apart in a wedge shape. As a result, solvent continues to flow into the bonding interface and the mechanical and chemical separation of the comprehensive substrate takes place.

In a fifth method step, as the separation process or separating continues to progress, the substrates are also pulled apart vertically in addition to being pulled apart in a wedge shape, in that the first and second substrate holders with the first and second substrates respectively attached to them move away from each other, in particular in steps. In a sixth method step, the substrates are completely separated from each other. In a seventh method step, the substrates are cleaned, dried and conveyed by means of a transport device into the storage device, in particular substrate boxes, and deposited.

A third exemplary embodiment of a method according to the present invention comprises the following steps, in particular carried out sequentially and/or simultaneously, in particular with the following sequence:

In preparation for the method for separating bonded comprehensive substrate, the comprehensive substrate is loaded into the device for separating bonded comprehensive substrate. In a first method step, an comprehensive substrate is held in place on a first substrate holder, in particular a lower substrate holder. In various embodiments of the method, the holding can be performed with vacuum fixation and/or preferably with mechanical fixation. In a second method step, the comprehensive substrate attached to a substrate holder is attached to a second substrate holder, in particular an upper substrate holder. The fixing can be carried out with vacuum fixing and/or preferably mechanical fixing.

In a third method step, the separation of the comprehensive substrate is initiated by introducing the mechanical means of separation or the mechanical tool, in particular a blade between the substrates of the comprehensive substrate, along the original bonding interface. In a fourth method step, in particular at the same time as the third method step, solvent is introduced from a nozzle element, in particular at high pressure, into the bonding interface at the blade. In this way, the release agent and the substrate are lubricated with the solvent so that the separation process is more conservative to the substrate.

As an alternative to introducing the solvent into the mechanically clamped bonding interface at high pressure, a defined volume of solvent, in particular a few milliliters, in particular a drop of solvent, can be introduced into the bonding interface at low pressure so that the capillary forces and/or surface tensions draw the solvent into the bonding interface.

Alternatively, clamping rings on the respective substrate edge can exert a force vertically to the bonding interface in the comprehensive substrate. In this way, the solvent gradually penetrates into the breaking bonding interface and separates the substrates from each other.

In a fifth method step, after this initial opening of the bonding interface of the comprehensive substrate by means of the blade and application of solvent to the bonding interface, the substrates are additionally mechanically tensioned. Preferably, they are tensioned in particular on the side on which the blade penetrates the bonding interface by applying a vertical tensile force that pulls the substrates apart in a wedge shape. As a result, solvent continues to flow through the bonding interface and the mechanical and chemical separation of the comprehensive substrate takes place.

In a sixth method step, as the separation process progresses further, in addition to the wedge-shaped pulling apart of the substrates, the substrates are also pulled apart vertically by the first and second substrate holders with the respective substrates attached to them moving away from each other gradually, in particular step by step. In a seventh method step, the substrates are completely separated from each other. In an eighth method step, the blade is preferably retracted to an initial position.

In a ninth method step, the substrates are cleaned, dried and conveyed by means of a transport device into the storage device, in particular substrate boxes, and deposited.

Preferably, methods in the device according to the invention are performed automatically. Measurement and control systems and computer-aided method steps are necessary for automation. Therefore, methods can be created, stored and performed as guidance manuals. Guidance manuals are optimized collections of values of parameters that are functionally or procedurally related. The use of guidance manuals makes it possible to ensure the reproducibility of production processes.

According to a further aspect of the present invention, a device for performing a method according to the invention is intended, i.e. a device for separating the first substrate and the second substrate from each other or for separating a comprehensive substrate, wherein the device comprises a means for non-chemical processing and an agent for chemical processing. All the advantages and properties described for the method can be transferred analogously to the device and vice versa. In the following, the device is also referred to as a separating device.

It is preferably intended that the means for non-chemical processing and the agnet for chemical processing are integrated into one tool component. This makes it particularly easy to simultaneously process the same point in the bonding interface with the tool component.

An exemplary device for separating preferably fusion-bonded comprehensive substrates may include at least one of the following functional units, wherein several similar units and/or functionally integrated units in one device may be advantageous according to the invention:
alignment device for reproducibly placing the comprehensive substrate to be separated in a receiving device, and
receiving device for receiving a comprehensive substrate to be separated in a receiving device, and
separating device with combined mechanical or optical means or means for accelerating particles and device for providing chemical agents, with holding devices, in particular a first substrate holder and/or a second substrate holder, dosing device for solvents, with movement devices for the separating device and in particular for the separated substrates, and
cleaning device, in particular with DI water for removing the particles from the substrate surfaces and/or creating OH bonds for renewed fusion bonding, and
drying device for drying the cleaned substrates free of particles, and
transport device for the first and/or second substrates and/or the comprehensive substrate, and
storage device for the comprehensive substrate and/or for separate substrates, and
supply modules for media, device for particle reduction, substrate recognition reading device. An exemplary device can advantageously have a modular design. A further development of the device for separating comprehensive substrates can be part of a complex fusion bonding device with measurement and reprocessing.

In particular, mechanical alignment devices, for example with notch detection and electronic-mechanical sensors, can be used for the alignment device so that substrates, i.e. first substrate, second substrate and/or comprehensive substrate, can be gently fixed in position.

In a further particularly advantageous embodiment of the device, an alignment device can comprise image acquisition means, in particular at least one camera system for the comprehensive substrate and/or substrate detection and/or substrate edge detection with corresponding control and computer-based data evaluation.

In a preferred device for separating comprehensive substrates, the comprehensive substrate, which has been joined together in particular from a first product substrate and from a second product substrate, is held in a holding device on a substrate holder.

The substrate holders can be
mechanical fixations, in particular clamps and/or
vacuum fixations, in particular with individually controllable vacuum paths or vacuum paths bonded with each other and/or
electrical fixations, in particular electrostatic fixations and/or
magnetic fixations and/or
adhesive fixations, in particular with gel pads or fixations with adhesive, in particular controllable surfaces. In particular, the fixations can be controlled electronically. For exemplary devices for separating comprehensive substrates, mechanical fixations of the comprehensive substrate have proven to be particularly advantageous.

A first embodiment of a separation device or a device for performing a method according to the invention with combined means for chemical and non-chemical processing comprises a trough for chemical processing of the comprehensive substrate to be separated with the solvent. The substrate holding device and the alignment device are integrated in the separation device so that a comprehensive substrate can be placed on loading pins, in particular in an automated manner, and attached to the substrate holding device in a correspondingly aligned manner.

The separation device is fluidically bonded to a media supply and a media discharge so that solvents can be dosed into the tray. The dosed amount of solvent varies depending on the design. However, it is generally the case that the solvent level must be above the level of the bonding interface of the comprehensive substrate in order to be able to perform the chemical separation. In particular, after each separation of the comprehensive substrate, the media drain removes the used and possibly used solvent from the tank. It has proven to be particularly advantageous if the tank can be cleaned between the separation processes, especially automatically. For cleaning, the tank can be advantageously rinsed with DI water in particular from cleaning nozzles that are bonded to the supply modules. The separating device can include a separating blade for mechanical separation of the comprehensive substrate.

In another embodiment of the separating device, it may include at least two separating blades which mechanically separate the comprehensive substrate from two opposite sides, in particular simultaneously.

In a further embodiment of the separating device, it can include at least one separating blade and at least one fluid nozzle that can be aligned with the bonding interface of the comprehensive substrate.

In a further embodiment of the separating device, it may include an integrated separating blade with at least one nozzle element or fluid nozzle. In the integrated separating blade with fluid nozzle, the fluid nozzle is functionally and materially bonded to the separating blade, so that the separating blade with the integrated nozzle can be moved with a movement device and/or positioning device. Thus, the separating device requires exactly one integrated positioning device for the nozzle element and for the separating blade.

In one conceivable embodiment of the separating device, it does not comprise a mechanical separating blade, but only at least one nozzle for the pure chemical separation of the comprehensive substrate. Designed in particular as a splitting nozzle or fan nozzle, the separating device can direct the solvent, especially at high pressure, into the immediate vicinity of the bonding layer so that the comprehensive substrate is separated. In particular at the same time, a clamping and lifting device can perform the mechanical separation of the comprehensive substrate.

In an alternative embodiment of the separation device, the substrate is immersed in the solvent at least up to the bonding interface to be separated and additional solvent is directed into the bonding interface with at least one nozzle at high pressure in order to initiate the separation of the comprehensive substrate. In particular, the clamping and lifting device can perform the mechanical separation of the comprehensive substrate at the same time.

All embodiments of the separation device can include at least one mechanical clamping and lifting device. The clamping and lifting device serves to hold the first substrate, in particular at the substrate edge and/or at the rear, and to loosen the comprehensive substrate with a normal separating force as reinforcement of the action of the separating blade and the solvent and, in particular, to lift the upper substrate from the lower substrate without transverse movement.

The advantage of the normal lifting of the first substrate from the second substrate is that in the case of structured substrates, the structures are not sheared in the separation process, which is undesirable for the structures.

Thus, according to the invention, comprehensive substrates, in particular structured substrates and/or substrates with through-hole plating and/or so-called hybrid bonds, can be gently separated from one another and re-bonded to one another in further method steps in a corrected manner.

A further embodiment of the clamping and lifting device of the separating device can, in particular, lift off the upper substrate in a fully clamping manner at the edge section where the separating blade was used. An alternative embodiment of the clamping and lifting device of the separating device can in particular clamp the upper substrate in approximately 180-degree sections with 2 jaws and lift it accordingly. The possibility of increasing the lifting with an additional vacuum device, which acts over the comprehensive substrate to be separated, is particularly advantageous. An alternative embodiment of the clamping and lifting device of the separating device can in particular clamp the upper substrate in approx. 90 degree sections with 4 jaws or in approx. 120 degree sections with 3 jaws and lift it accordingly. It is possible to increase the number of discrete clamping jaws so that the effect of full clamping can be achieved. The angle specifications correspond to the technology, in particular special machine construction usual basic tolerances not tolerated values according to ISO 22081. The second and/or first substrate can remain clamped in particular mechanically on the first and/or second substrate holder of the substrate holding device.

The exemplary device for separating comprehensive substrates may preferably include at least one separating device. The separating device includes the dosing device for the solvent, so that each comprehensive substrate to be separated is treated with freshly formulated and/or freshly purified solvent. This prevents cross-contamination between the substrates.

If water, in particular DI water, is used as the solvent, the solvent can be filtered, purified and reused in the cycle to separate the comprehensive substrate.

The dosing device for the solvent of the separation device can be designed in particularly preferred embodiments as at least one alignable and/or movable nozzle element, with which the bonding interface of the comprehensive substrate to be separated can be treated with solvent with overpressure, so that the chemical separation reaction can take place at an increased reaction rate. The volume of the solvent for the separation of a comprehensive substrate is less than 50 ml, preferably less than 5 ml, more preferably less than 1 ml, most preferably less than 0.1 ml, in the optimum case less than 0.01 ml. Fan nozzles or slit nozzles, which apply a linear force to the bonding interface, are particularly advantageous.

This results in a more conservative separation than when using nozzles that emit the solvent similar to a coherent jet and act on the bonding interface over a small area similar to a point.

In a further embodiment of the dosing device for the solvent of the separating device according to the invention, the movable nozzle element and the separating blade form an integrated unit, so that the separate alignment and movement of the dosing device can be omitted. This embodiment is advantageous for dosing, in particular for a drop of solvent for separating the comprehensive substrate, which is separated mechanically, in particular simultaneously with the blade.

The exemplary device for separating comprehensive substrates can preferably include a cleaning device. In particular, the cleaning device uses DI water to remove any particles from the substrate surfaces after separation of the comprehensive substrate and/or uses DI water to create OH bonds on plasma-treated substrate surfaces for renewed fusion bonding. The exemplary device for separating comprehensive substrates may preferably comprise a transport device for substrates and/or comprehensive substrate. The transport device for substrates and/or the comprehensive substrate may in particular be at least one robot with at least one end effector comprising a part of the device for separating comprehensive substrates, in particular according to the present invention. Transport devices with at least two specialized end effectors have proven advantageous for reducing the cycle time of the device: at least one end effector can transport at least one comprehensive substrate and at least one end effector can transport at least one separated substrate. It is advantageous for reducing the cycle time of the device for separating comprehensive substrates that at least one end effector of the transport device is specialized for transporting the comprehensive substrate and two end effectors can in particular simultaneously pick up and transport at least two separate substrates.

The exemplary device for separating comprehensive substrates can preferably include a drying device. The drying device makes it possible to dry the cleaned substrates without particles, in particular by utilizing the Marangoni effect. For this purpose, the separated substrates can at least be brought into contact with dry gas or other solvents. Further drying options in the possible embodiments according to the invention can also include centrifugal devices and/or heating plates.

The exemplary device for separating comprehensive substrates may preferably include a storage device for substrates and/or comprehensive substrate. The storage device for the comprehensive substrate and/or for separated substrates includes in particular both the pick-up and handling device and the transfer device for the transport device as well as optionally intermediate storage, bake-out devices in the form of heating plates.

The storage device is designed to be particularly flexible for at least two common substrate sizes (especially wafer sizes), so that 200 mm wafers and 300 mm wafers can be stored, transported and separated without adapting the device.

In particular, the device for separating comprehensive substrates can be advantageously converted for each substrate shape and substrate size.

The first substrate, the second substrate and/or the comprehensive substrate, i.e. the substrates, can have any shape, but are preferably circular. In particular, the diameter of the substrates is standardized in the industry. For wafers, the industry-standard diameters are 1 inch, 2 inches, 3 inches, 4 inches, 5 inches, 6 inches, 8 inches, 12 inches and 18 inches.

The embodiments of the device can basically handle any substrate, regardless of its diameter. Square substrates, also known as panels, are subsumed as substrates.

The exemplary device for separating comprehensive substrates can preferably have a modular design. Modules are to be understood as functional units of the device, which in particular have standardized sizes and are bonded in the device via standardized interfaces.

This enables cost-effective conversion and adaptation of the device according to the invention if empty module spaces in the device are expanded and/or newly occupied with individual modules.

A further development of the device according to the invention for separating overall substrates can be a part of a complex fusion bonding device with measurement of the alignment and/or the edge defects and reprocessing.

Further advantages, features and details of the invention will be apparent from the following description of preferred embodiments and from the drawings.

These show in:

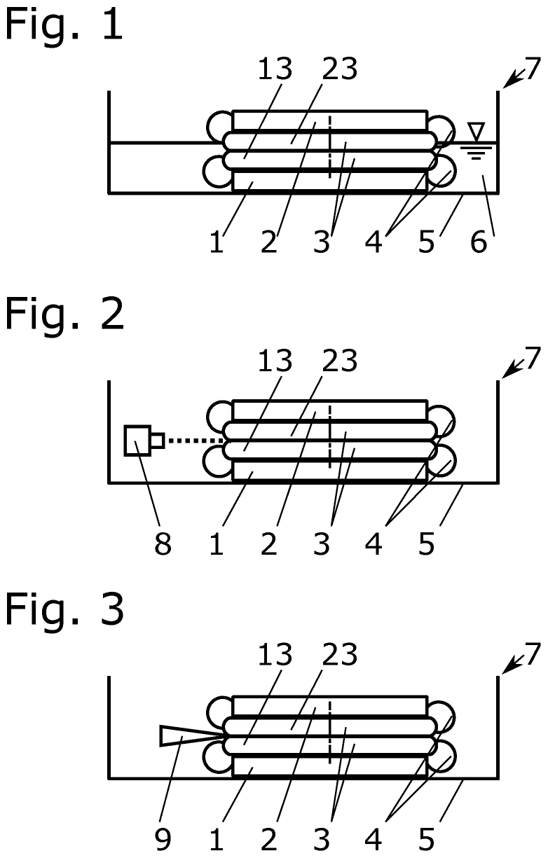

FIG. 1 schematically an implementation of a process step according to a first exemplary embodiment of the present invention.

FIG. 2 schematically illustrates a method step according to a second exemplary embodiment of the present invention, and

FIG. 3 schematically illustrates a method step according to a third exemplary embodiment of the present invention.

In the figures, identical components or components with the same function are marked with the same reference signs.

FIG. 1 schematically shows a performance of a method step according to a first exemplary embodiment of the present invention, performed with an exemplary device according to the present invention, which is shown as a schematic structural sketch.

Such a device 7 for separating a comprehensive substrate 3 into a first substrate 13 and a second substrate 23 comprises a first, in particular lower, substrate holder 1 and a second, in particular upper, substrate holder 2. The comprehensive substrate 3 to be separated is fastened to the first substrate holder 1 with mechanical clamps 4. Preferably, the second substrate 23 of the comprehensive substrate 3 can be additionally fastened to the upper substrate holder 2 with further mechanical clamps 4. The first substrate holder 1 with the mechanical clamps 4 and with the comprehensive substrate 3 to be separated is located in a trough 5 for the chemical separation of the comprehensive substrate 3. For this purpose, liquid solvent 6 is fed into the trough 5 up to above a bonding interface, which forms a planned separation plane, so that the solvent 6 penetrates into the bonding interface and can separate the comprehensive substrate 3 into the first substrate 13 and the second substrate 23.

FIG. 2 schematically shows a procedure of a method step according to a second exemplary embodiment of the present invention, which is shown as a schematic structural sketch.

The device 7 for separating the comprehensive substrate 3 also comprises a first, in particular lower, substrate holder 1 and a second, in particular upper, substrate holder 2. The comprehensive substrate 3 to be separated is fixed to the first substrate holder 1 by means of mechanical clamps 4. Preferably, the second substrate 23 of the comprehensive substrate 3 can be additionally fastened to the second substrate holder 2 with further mechanical clamps 4. The first substrate holder 1 with the mechanical clamps 4 and with the comprehensive substrate 3 to be separated is located in the trough 5 for chemical separation of the comprehensive substrate 3. In the method step shown, the comprehensive substrate 3 is separated with a nozzle element 8, in particular with a nozzle which directs solvent 6 into the bonding interface. The solvent 6 penetrates into the bonding interface and enables the separation of the comprehensive substrate 3 along the separation plane or the bonding interface.

FIG. 3 shows schematically a procedure of a method step according to a third exemplary embodiment of the present invention, which is shown as a schematic structural sketch.

The device 7 for separating comprehensive substrates 3 includes a first, in particular lower, substrate holder 1 and a second, in particular upper, substrate holder 2. The comprehensive substrate 3 to be separated is fastened to the first substrate holder 1 with mechanical clamps 4. Preferably, the second substrate 23 of the comprehensive substrate 3 can be additionally fastened to the upper substrate holder 2 with further mechanical clamps 4. The first substrate holder 1 with the mechanical clamps 4 and with the comprehensive substrate 3 to be separated is located in a trough 5 for the chemical separation of the comprehensive substrate 3, in particular for collecting the liquid solvent, not shown, which promotes the separation of the comprehensive substrate 3. In the method step shown, the comprehensive substrate 3 is separated using a mechanical tool 9, in particular a wedge, which is guided into the bonding interface. To accelerate the separation of the comprehensive substrate 3, the liquid solvent, which is not shown, can be passed into the trough 5 via the bonding interface in order to lubricate the mechanical tool 9. The solvent penetrates into the bonding interface and enables the separation of the comprehensive substrate 3.

### LIST OF REFERENCE SIGNS

1 first substrate holder
2 second substrate holder
3 comprehensive substrate
4 clamp
5 trough
6 solvent
7 device
8 nozzle element
9 tool
13 first substrate
23 second substrate

1.-15. (canceled)

16. A method for separating an entire substrate into a first substrate and a second substrate, wherein the first substrate and/or the second substrate is intended as an element of an electronic component, comprising:
providing the entire substrate comprising the first substrate and the second substrate, wherein the first substrate and the second substrate are bonded with each other via a bond created along a bonding interface, wherein, to form a reservoir which is provided for storing a fluid prior to bonding the first substrate with the second substrate, at least one substrate surface of the first substrate or the second substrate is plasma-activated, and
separating the entire substrate into the first substrate and the second substrate along the bonding interface,
wherein, to separate the entire substrate into the first substrate and the second substrate, a means for chemical processing and preferably a means for non-chemical processing is used, wherein a solvent for shifting a reaction equilibrium, preferably according to Le Chatelier's principle, is used as the means for chemical processing, wherein the solvent is stored in the first substrate and/or second substrate, in particular in such a way that an oversaturation is set in the region of the bonding interface.

17. The method according to claim 16, wherein the entire substrate is held together by Van der Waals forces, in particular is a prebond, and preferably the bond created is a bond created by a fusion bond.

18. The method according to claim 16, wherein the first substrate and the second substrate are pulled apart in response to the means for non-chemical processing, in particular in a wedge-shaped manner.

19. The method according to claim 16, wherein a substrate holding system with a first substrate holder and a second substrate holder is used as a means for non-chemical processing, wherein the first substrate is fixed in a first substrate holder and the second substrate is fixed in a second substrate holder, wherein, during separating, in addition to the action of the means for chemical processing, the first substrate holder and the second substrate holder are moved apart.

20. The method according to claim 16, wherein a separating force is caused to act on the first substrate and on the second substrate, wherein the separating force acts perpendicular to a main extension plane of the first substrate and/or the second substrate.

21. The method according to claim 16, wherein a mechanical tool is used as a means for non-chemical processing or as a further means for non-chemical processing.

22. The method according to claim 21, wherein the solvent is stored in the first substrate and/or second substrate to form a reservoir, in particular in such a way that an oversaturation is set in the region of the bonding interface.

23. The method according to claim 21, wherein a chemical bond in the region of the bonding interface is separated by hydrolysis.

24. The method according to claim 21, wherein the solvent is directed onto the bonding interface by means of a nozzle element.

25. The method according to claim 16, wherein after separating, the first substrate and/or the second substrate is cleaned by means of a cleaning device and/or dried by means of a drying device.

26. The method according to claim 16, wherein a solvent supply is set by means of a dosing device.

27. A device for performing a method according to any of the preceding claims for separating an entire substrate, comprising the first substrate and the second substrate, wherein the first substrate and the second substrate are bonded with each other via a bond created along a bonding interface, wherein to form a reservoir which is provided for storing a fluid prior to bonding the first substrate with the second substrate, at least one substrate surface of the first substrate or the second substrate is plasma-activated, wherein the device comprises a means for non-chemical processing and a feature for providing a means for chemical processing,
wherein the means for chemical processing is a solvent for shifting a reaction equilibrium, preferably according to Le Chatelier's principle, and wherein the solvent is stored in the first substrate and/or second substrate in the reservoir, in particular in such a way that an oversaturation is set in the region of the bonding interface.

28. The device according to claim 27, wherein the means for non-chemical processing and the means for chemical processing are integrated into a single tool component.

29. The device according to claim 27, wherein the device comprises a first substrate holder for fixing to the first substrate and a second substrate holder for fixing to the second substrate, wherein a distance between the first substrate holder and the second substrate holder is variable.
